(19) United States
(12) Patent Application Publication
(10) Pub. No.: US 2023/0387151 A1
(43) Pub. Date: Nov. 30, 2023

(54) IMAGE SENSOR

(71) Applicant: Tianma Japan, Ltd., Kawasaki (JP)

(72) Inventor: Yusuke YAMAMOTO, Kawasaki (JP)

(21) Appl. No.: 18/322,293

(22) Filed: May 23, 2023

(30) Foreign Application Priority Data
May 26, 2022 (JP) 2022-086121

(51) Int. Cl. H01L 27/146

(52) U.S. Cl. CPC H01L 27/14616

(57) ABSTRACT

An image sensor includes pixels arrayed on a substrate and a data line that transmits a signal read from each of the pixels. The pixel includes a photodetector and an N-type switch thin film transistor between the photodetector and the data line. The switch thin film transistor includes an oxide semiconductor part, a gate electrode, a drain electrode towards the data line, and a source electrode towards the photodetector. An overlap region where the gate electrode and the drain electrode overlap in a plan view is smaller than an overlap region where the gate electrode and the source electrode overlap in a plan view.

### CROSS-REFERENCE TO RELATED APPLICATIONS

This non-provisional application claims priority under 35 U.S.C. § 119(a) on Patent Application No. 2022-086121 filed in Japan on May 26, 2022, the entire content of which is hereby incorporated by reference.

### BACKGROUND

This disclosure relates to an image sensor.

A technique by which the inside of a specimen can be subjected to non-destructive testing through X-ray imaging is indispensable in medicine and industrial non-destructive testing. In particular, digital radiography (DR) in which an X-ray image is directly acquired as electronic data has become widely used due to allowing for rapid image reading, aiding of image reading through image processing, and the like. Image sensors referred to as flat-panel detectors (FPDs) are used in DR, and the image sensors have a structure in which pixels having photoelectric conversion elements and switching elements are arranged in an array.

Higher resolution flat-panel detectors (FPDs) used in X-ray sensors and the like are being developed. FPDs used in X-ray sensors are typically classified as a direct conversion type or an indirect conversion type. Direct conversion-type FPDs use a photoelectric conversion element that directly converts X-rays into electrical signals using amorphous selenium, CdTe, or the like. Indirect conversion-type FPDs use an X-ray detection panel having a phosphor (scintillator) that converts X-rays into light such as visible light or ultraviolet light, for example, and converts the light into an electrical signal.

### SUMMARY

An image sensor according to an aspect of the present disclosure includes pixels arrayed on a substrate and a data line that transmits a signal read from each of the pixels. The pixel includes a photodetector; and an N-type switch thin film transistor between the photodetector and the data line. The switch thin film transistor includes an oxide semiconductor part, a gate electrode, a drain electrode towards the data line, and a source electrode towards the photodetector. An overlap region where the gate electrode and the drain electrode overlap in a plan view is smaller than an overlap region where the gate electrode and the source electrode overlap in a plan view.

It is to be understood that both the foregoing general description and the following detailed description are exemplary and explanatory and are not restrictive of this disclosure.

### BRIEF DESCRIPTION OF THE DRAWINGS

FIG. 1 is a block diagram showing a configuration example of an image sensor according to one embodiment of the present specification.

FIG. 2 is a circuit diagram showing an equivalent circuit of one pixel.

FIG. 3A is a plan view schematically showing the structure of the pixel, the gate line, and the data line.

FIG. 3B is a cross-sectional view of FIG. 3A along the line 111B-1116′.

FIG. 4A is a plan view that schematically shows an example of the structure of the thin film transistor.

FIG. 4B is a cross-sectional view that schematically shows an example of a cross-sectional structure along the line IVB-IVB′ of FIG. 4A.

FIG. 5A is a cross-sectional view that schematically shows a cross-sectional structure of the thin film transistor where the offset is 0.

FIG. 5B is a cross-sectional view that schematically shows a cross-sectional structure of the thin film transistor where the offset is A.

FIG. 6 shows simulation results of the structural example described with reference to FIGS. 4A to 5B of the relationship (Id-Vg characteristics) between the gate voltage Vg and the drain current Id of the thin film transistor at different offset values.

FIG. 7 shows simulation results of the relationship between the offset and the drain current Id for a gate voltage of 15V.

FIG. 8 shows simulation results of the relationship between the offset of the thin film transistor and the TFT capacitance Ctft between the gate electrode and the drain electrode.

FIG. 9 shows simulation results for the relationship between the TFT capacitance Ctft and the data line capacitance Cdata.

FIG. 10 shows simulation results for the relationship between the data line capacitance and noise in the data line (line noise).

FIG. 11 shows simulation results of the relationship between the offset and the TFT capacitance Ctft for an etch stop-type thin film transistor and a channel etch-type thin film transistor.

FIG. 12 shows a structural example of the thin film transistor including a gate electrode having a shape that is asymmetrical between the source electrode side and the drain electrode side.

FIG. 13 shows a structural example of the thin film transistor including a gate electrode having a shape that is asymmetrical between the source electrode side and the drain electrode side.

FIG. 14 shows a structural example of the thin film transistor including a gate electrode having a shape that is asymmetrical between the source electrode side and the drain electrode side.

### DETAILED DESCRIPTION OF EMBODIMENTS

Embodiments of the present disclosure will be explained below in detail with reference to the drawings. The size and scale of each constituent element in the drawings have been modified as appropriate to improve the clarity of the drawings. The hatch lines in the drawings are for distinguishing the constituent elements from each other, and do not necessarily indicate a cross-sectional view. Non-linear elements used as switching elements or amplifiers are referred to as transistors, and transistors include thin film transistors (TFTs).

One embodiment of the present specification is an image sensor. The image sensor of the present disclosure can be used in a radiographic imaging device in fields such as medicine and industrial non-destructive testing, for example. Light detected by the image sensor can be an electromagnetic wave of a given frequency including X-rays in addition to infrared and visible light.

The S/N ratio is used as an indicator for the sensitivity of an image sensor. In order to achieve a high S/N ratio, the sensitivity needs to be increased, and noise needs to be decreased. Noise in an image sensor includes noise occurring in a pixel, line noise occurring in a data line, and the like. Line noise occurring in the data line includes Johnson noise, which includes the data line capacitance Cdata as a parameter, thermal noise of an amplifier, and the like. By reducing the data line capacitance Cdata, it is possible to reduce line noise.

Data line capacitance primarily includes the following elements: the capacitance formed between the gate electrode and the drain electrode of a switch thin film transistor in a pixel connected to a data line; the capacitance formed at the intersection between the data line and the gate line; and the capacitance formed between the data line and a bias line. In a typical pixel configuration, the capacitance of the thin film transistor (TFT capacitance Ctft) takes up 30-40% of the entire data line capacitance Cdata. Effective methods for reducing Ctft include reducing the channel width of the thin film transistor, modifying the thickness or the permittivity of an interlayer insulating film, or the like. However, such measures can have a major impact on the characteristics of the thin film transistor.

An image sensor according to one embodiment of the present specification includes pixels, and data lines that transmit read signals from the pixels. The pixels each include a photodetector and an N-type switch thin film transistor that is connected between the photodetector and the data line. In reading a signal from the pixel, the electrode of the switch thin film transistor towards the data line is the drain electrode and the electrode of the switch thin film transistor towards the photodetector is the source electrode. An overlap region where the gate electrode and the drain electrode overlap in a plan view is smaller than an overlap region where the gate electrode and the source electrode overlap in a plan view. As a result, by reducing the data line capacitance while mitigating a change in thin film transistor characteristics, it is possible to improve the S/N ratio of the image sensor.

### [Image Sensor Configuration]

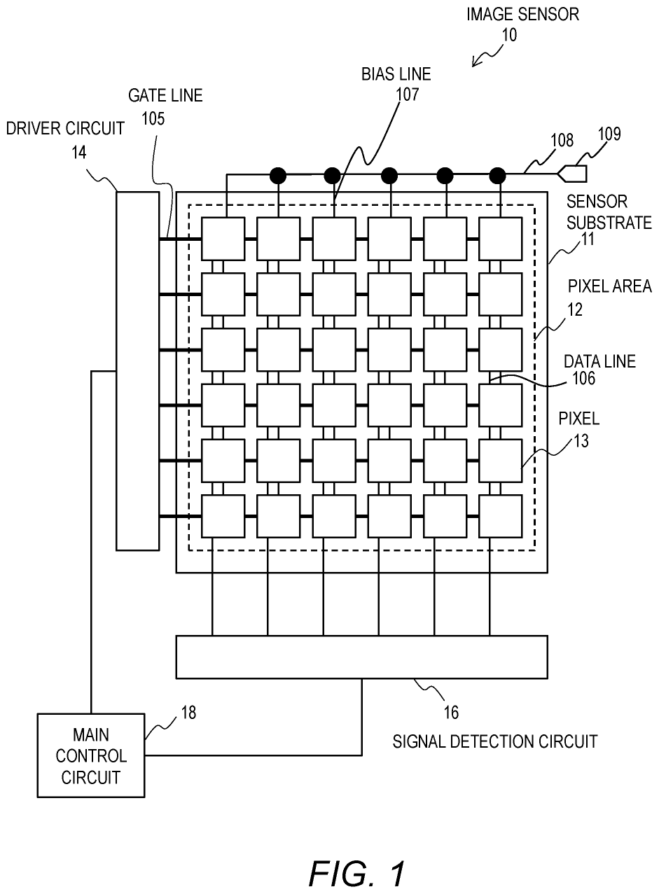

FIG. 1 is a block diagram showing a configuration example of an image sensor according to one embodiment of the present specification. The image sensor 10 includes a sensor substrate 11 and control circuits. The control circuits include a driver circuit 14, a signal detection circuit 16, and a main control circuit 18.

The sensor substrate 11 includes an insulating substrate (e.g., a glass substrate), and a pixel area 12 where pixels 13 are arranged in a matrix in the vertical and horizontal directions on the insulating substrate. The pixels 13 are elements on the substrate including the photodetectors. The layout of the pixels 13 is not limited to being the matrix layout shown in FIG. 1. In an example of an X-ray image sensor, the pixel area 12 has disposed therein a scintillator that receives radiation that is detection light to produce fluorescence.

The pixels 13 are disposed at each intersection of a plurality of data lines 106 that extend in the vertical direction and are arrayed horizontally, and a plurality of gate lines 105 (scanning lines) that extend in the horizontal direction and are arrayed vertically in FIG. 1. The pixels 13 are each connected to bias lines 107 that extend in the vertical direction and are arrayed horizontally in FIG. 1. In FIG. 1, only one pixel, one data line, one gate line, and one bias line are indicated, respectively, with reference characters 13, 106, 105, and 107.

The data lines 106 are each connected to different pixel columns. The gate lines 105 are each connected to different pixel rows. The data lines 106 are connected to the signal detection circuit 16, and the gate lines 105 are connected to the driver circuit 14. The bias lines 107 are connected to a common bias line 108. A bias potential is applied to a pad 109 of the common bias line 108. The driver circuit 14 drives the gate lines 105 of the pixels 13 in order for the pixels 13 to detect light. The signal detection circuit 16 detects signals from the respective data lines. The main control circuit 18 controls the driver circuit 14 and the signal detection circuit 16.

### [Pixel Circuit Configuration]

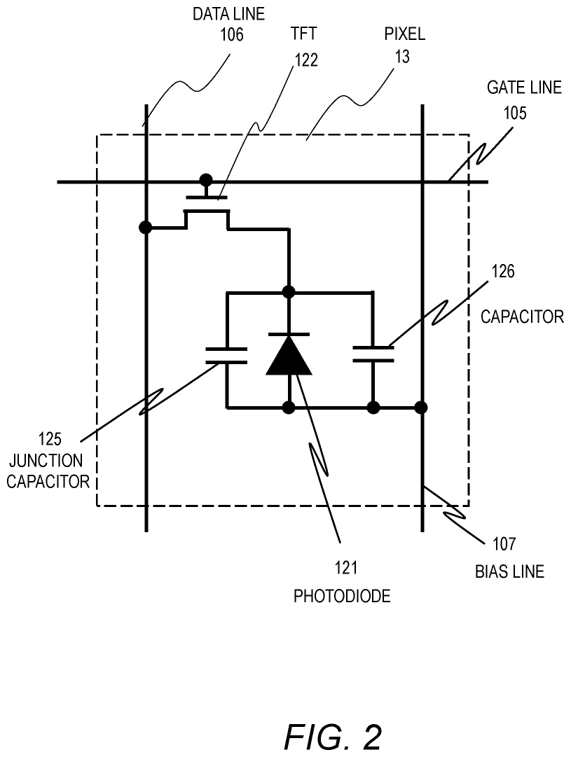

FIG. 2 is a circuit diagram showing an equivalent circuit of one pixel 13. The pixel 13 includes a photodiode 121 that is a photoelectric conversion element and a thin film transistor 122 (TFT) that is a switching element. In the thin film transistor 122, the gate terminal is connected to the gate line 105, the drain terminal is connected to the data line 106, and the source terminal is connected to the cathode terminal of the photodiode 121. In the example of FIG. 2, the anode terminal of the photodiode 121 is connected to the bias line 107.

The thin film transistor 122 is, for example, an oxide semiconductor thin film transistor. Examples of the oxide semiconductor include IGZO (InGaZnO) and ZnO. In one embodiment of the present specification, the conductivity type of the thin film transistor 122 is the N type.

The pixel 13 further includes a junction capacitor 125 and a capacitor 126 of the photodiode 121. The junction capacitor 125 and the capacitor 126 are connected in parallel to the photodiode 121 between the switch TFT 122 and the bias line 107.

The image sensor 10 used as an X-ray imaging device accumulates, in the junction capacitor 125 and the capacitor 126, a signal charge corresponding to the quantity of light emitted to the photodiode 121. As a result of the pixel 13 including the capacitor 126 in addition to the junction capacitor 125 of the photodiode 121, it is possible to improve the saturation signal volume with almost no change in manufacturing conditions for the photodiode. The capacitor 126 may be omitted.

The main control circuit 18 causes the thin film transistor 122 disposed in the pixel 13 to become conductive, and extracts the charge accumulated in the junction capacitor 125 and the capacitor 126 to the outside, thereby reading the signal.

Specifically, the driver circuit 14 sequentially selects each of the gate lines 105 and applies a pulse that sets each thin film transistor 122 to a conductive state. The anode terminal of the photodiode 121 is connected to the bias line 107, and a reference potential is applied to the data line 106 by the signal detection circuit 16. As a result, a difference voltage between the bias potential of the bias line 107 and the reference potential is used to charge the photodiode 121. Typically, this difference voltage is set to a reverse bias voltage whereby the cathode potential exceeds the anode potential.

The electric charge necessary for recharging the photodiode 121 to the reverse bias voltage is dependent on the intensity of light emitted onto the photodiode 121. The signal detection circuit 16 reads the signal charge by integrating the current that flows when the photodiode 121 is recharged up to reverse bias voltage.

In reading the signal charge, the voltage of the terminal of the thin film transistor 122 connected to the data line 106 is greater than or equal to the voltage of the terminal connected to the photodiode 121. That is, in detecting the signal charge, the terminal of the thin film transistor 122 connected to the data line 106 is the drain and the terminal connected to the photodiode 121 is the source. The pixel 13 may include an additional constituent element (not shown) in addition to the constituent elements shown in FIG. 2, such as an additional thin film transistor, for example.

### Pixel Structure Example

Below, some examples of the device structure of the pixel 13 will be described. The photodiode 121, the thin film transistor 122, and the capacitor 126 included in the pixel 13 respectively have a laminate structure on an insulating substrate.

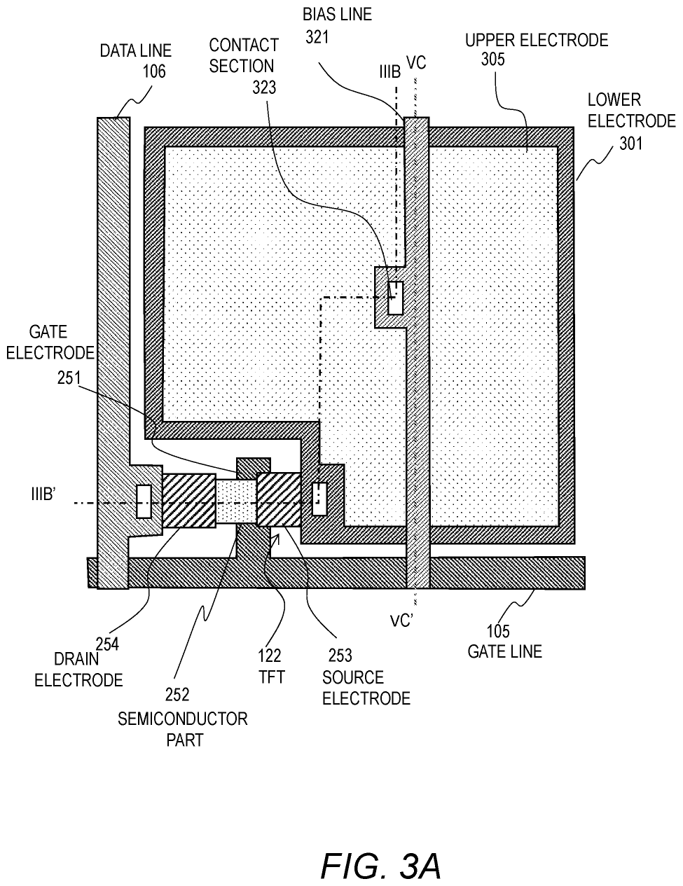

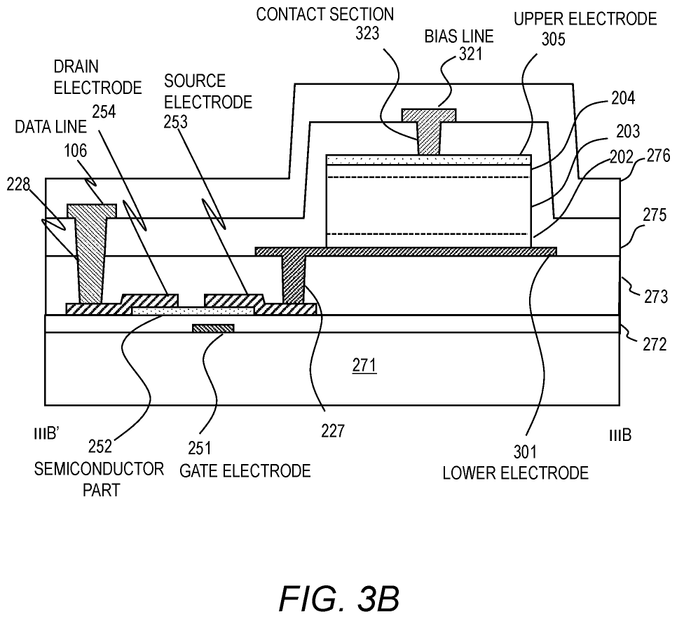

FIG. 3A is a plan view schematically showing the structure of the pixel 13, the gate line 105, and the data line 106. In FIG. 3A, the data line 106 extends in the vertical direction, the gate line 105 extends in the horizontal direction, and a thin film transistor 122 is disposed at the intersection therebetween.

The pixel 13 includes a lower electrode 301 and an upper electrode 305. In the configuration example of FIG. 3A, the entire area of the upper electrode 305 overlaps the lower electrode 301 in a plan view. That is, in a plan view, the entire area of the upper electrode 305 is included within the region of the lower electrode 301. As will be described later, the photodiode 121 is sandwiched between the lower electrode 301 and the upper electrode 305.

The pixel 13 further includes the thin film transistor 122 and a bias line 321. The thin film transistor 122 includes a gate electrode 251, an insular semiconductor part 252, a source electrode 253, and a drain electrode 254. The gate electrode 251, the source electrode 253, and the drain electrode 254 are respectively regions of the conductive film that face the semiconductor part 252.

The bias line 321 extends in the vertical direction of FIG. 3A. The bias line 321 is in a layer above the upper electrode 305, and is connected via a contact section 323 to the upper electrode 305 of the plurality of pixels 13. The bias line 321 passes over the upper electrode 305 from one edge of the upper electrode 305 to the opposite edge thereof. The bias line 321 transmits the bias potential.

In the configuration example of FIG. 3A, the lower electrode 301 and the upper electrode 305 do not overlap the gate line 105 or the data line 106 in a plan view, and are separated therefrom. Neither the lower electrode 301 nor the upper electrode 305 overlap the semiconductor part 252 in a plan view, and are separated therefrom.

Next, the cross-sectional structure of the pixel 13 shown in FIG. 3A will be described. FIG. 3B is a cross-sectional view of FIG. 3A along the line IIIB-IIIB′. Below, the reference characters of some elements in the drawing are omitted.

With reference to FIG. 3B, the thin film transistor 122 includes the gate electrode 251 formed on an insulating substrate 271, a gate insulating layer 272 on the gate electrode 251, and the semiconductor part 252 on the gate insulating layer 272. In the relationship between the two layers, the layer closer to the substrate 271 is referred to as the lower layer and the layer farther from the substrate 271 is referred to as the upper layer.

As shown in FIG. 3A, the gate electrode 251 is an upwardly protruding portion of the gate line 105, which extends in the horizontal direction, and that is a region overlapping the semiconductor part 252 in the lamination direction. The gate electrode 251 and the gate line 105 are formed on the insulating substrate 271 (insulating layer), and are included in the same conductive layer. A silicon insulating layer may be provided between the insulating substrate 271 and the layer including the gate electrode 251 and the gate line 105.

The continuous or divided conductor parts formed in the same conductive layer are made of the same layer on the same insulating layer and in direct contact therewith. During manufacturing, the conductor parts of the same conductive layer are formed in the same step. The conductive layer can have a single layer structure or a laminate structure.

In the present configuration example, the thin film transistor 122 has a bottom gate structure, whereby the gate electrode 251 is present below the semiconductor part 252, or in other words, at a position closer to the substrate 271. The thin film transistor 122 further includes the source electrode 253 and the drain electrode 254 on the gate insulating layer 272. The source electrode 253 and the drain electrode 254 are included in the same conductive layer.

The electrode 253 is the source electrode and the electrode 254 is the drain electrode because of the flow of the carrier during detection of the charge of the photodiode 121. The source electrode 253 and the drain electrode 254 are respectively regions of the conductive film that overlap the semiconductor part 252 in a plan view. The source electrode 253 and the drain electrode 254 are in direct contact with the semiconductor part 252. The source electrode 253 and the drain electrode 254 are formed so as to be in contact with the side faces and a portion of the top surface of the insular semiconductor part 252.

The gate insulating layer 272 is formed so as to cover the entire surface of the gate electrode 251. The gate insulating layer 272 is formed between the gate electrode 251 and the semiconductor part 252. A first interlayer insulating layer 273 covers the entire thin film transistor 122. Specifically, the first interlayer insulating layer 273 covers the top surface of the semiconductor part 252 and the top surfaces of the source electrode 253 and the drain electrode 254.

The substrate 271 is made of glass or resin, for example. The gate electrode 251 is a conductor, and can be made of a metal such as Mo or Cr, an alloy thereof, or a laminate thereof. The gate insulating layer 272 is made of a silicon thermal oxide, for example. The semiconductor forming the semiconductor part 252 is an oxide semiconductor, for example. The oxide semiconductor includes at least one of In, Ga, and Zn, for example, and an example thereof is amorphous InGaZnO (a-InGaZnO) or microcrystalline InGaZnO.

The source electrode 253 and the drain electrode 254 are both conductors, and can be made of a metal such as Ti or Al, an alloy thereof, or a laminate thereof. The first interlayer insulating layer 273 is an inorganic or organic insulator.

The lower electrode 301 is connected to the conductive film including the source electrode 253 of the thin film transistor 122 via a contact section 227 in a via hole formed in the first interlayer insulating layer 273. The lower electrode 301 is a conductor, for example, and can be made of a metal such as Cr, Mo, or Al, an alloy thereof, or a laminate thereof.

The photodiode 121 is constituted of a photoelectric conversion part between the lower electrode 301 and the upper electrode 305, and portions of the lower electrode 301 and upper electrode 305 in contact with the photoelectric conversion part. The example of the photodiode 121 shown in FIG. 3B is a PIN diode. The PIN diode can efficiently detect light as a result of a depletion layer being formed to be wide in the thickness direction. The upper electrode 305 is an electrode that is transparent to light from the scintillator, and is ITO, for example.

The photoelectric conversion part of the photodiode 121 includes an N-type amorphous silicon layer (film) 202 on the lower electrode 301, an intrinsic amorphous silicon layer (film) 203 formed on the N-type amorphous silicon layer 202, and a P-type amorphous silicon layer (film) 204 formed on the intrinsic amorphous silicon layer 203. In the present configuration example, the N-type amorphous silicon layer 202 is in direct contact with the lower electrode 301.

The upper electrode 305 is formed on the P-type amorphous silicon layer 204. In the present configuration example, the upper electrode 305 is in direct contact with the P-type amorphous silicon layer 204. The light to be detected enters the photodiode 121 from the upper electrode 305 side. The positions of the N-type amorphous silicon layer 202 and the P-type amorphous silicon layer 204 may be reversed, and the intrinsic amorphous silicon layer 203 may be omitted.

A second interlayer insulating layer 275 is formed so as to cover the lower electrode 301, the silicon layers 202 to 204, and the upper electrode 305. The second interlayer insulating layer 275 is an inorganic or organic insulator. The bias line 321 and the data line 106 are formed on the second interlayer insulating layer 275. In this example, the bias line 321 and the data line 106 are in direct contact with the second interlayer insulating layer 275. The data line 106 is connected to the conductive film including the drain electrode 254 of the thin film transistor 122 via a contact section 228 in a via hole formed in the second interlayer insulating layer 275 and the first interlayer insulating layer 273.

The bias line 321 is connected to the upper electrode 305 via a contact section 323 in a via hole formed in the second interlayer insulating layer 275. The bias line 321 is a conductor, for example, and can be made of a metal such as Ti or Al, an alloy thereof, or a laminate thereof.

A passivation layer 276 is formed so as to cover the data line 106, the bias line 321, and the second interlayer insulating layer 275. The passivation layer 276 covers the entire pixel area 12. The passivation layer 276 is an inorganic or organic insulator. A scintillator (not shown) is disposed above the passivation layer 276.

The scintillator (not shown) covers the entire pixel area 12. The scintillator emits light by being excited by radiation. Specifically, the scintillator converts incident X-rays into light of a wavelength detectable by the photodiode 121. The photodiode 121 generates a signal charge according to the light from the scintillator and stores the signal charge in the junction capacitor 125 and the capacitor 126 (see FIG. 2).

### [TFT Structure]

Below, an example of the structure of the thin film transistor 122 in the pixel will be described. In the thin film transistor 122 according to one embodiment of the present specification, the capacitance between the gate electrode and the drain electrode is less than the capacitance between the gate electrode and the source electrode. As a result, it is possible to reduce the data line capacitance while reducing the effect on characteristics of the thin film transistor 122. As described above, the capacitance between the gate electrode and the drain electrode is included in data line capacitance.

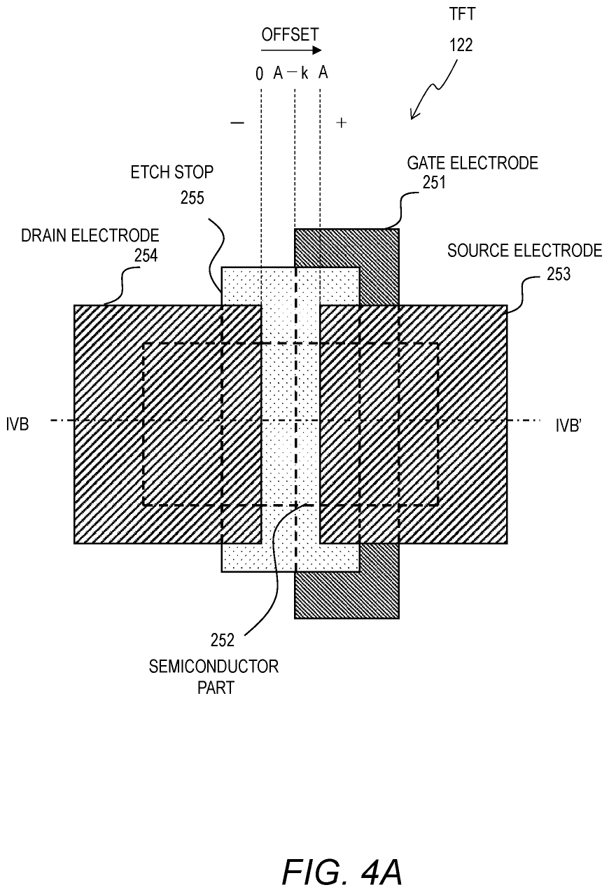

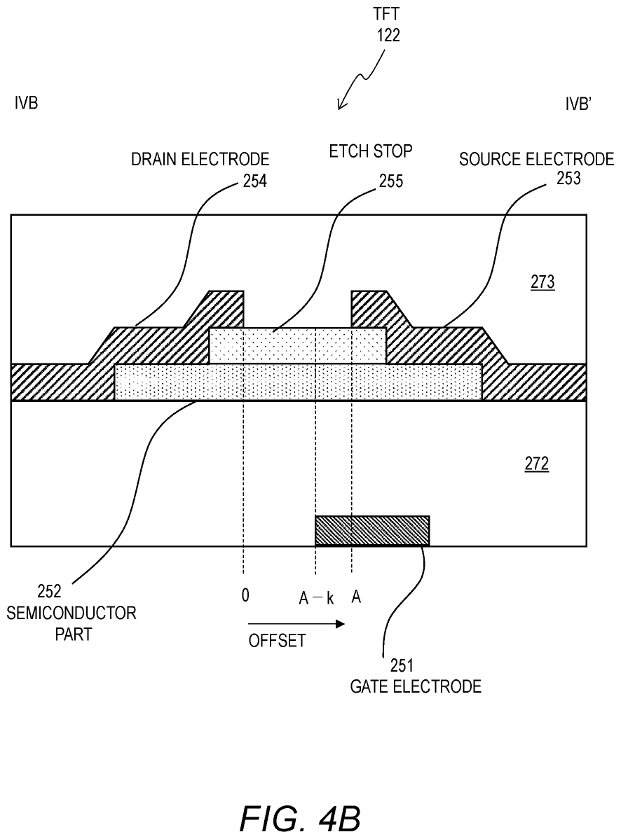

FIG. 4A is a plan view that schematically shows an example of the structure of the thin film transistor 122, and FIG. 4B is a cross-sectional view that schematically shows an example of a cross-sectional structure along the line IVB-IVB′ of FIG. 4A. In FIG. 4A, a portion of one constituent element covered by another constituent element is indicated with broken lines.

As shown in FIG. 4A, this structural example includes a rectangular source electrode 253 and a rectangular drain electrode 254. The shapes thereof may be the same, or may differ from each other. For ease of depiction, the reference characters 253 and 254 indicate conductive films including the source electrode and the drain electrode. This similarly applies to the rectangular gate electrode 251 as well. The semiconductor part 252 is rectangular. The shape of the constituent elements of the thin film transistor 122 may differ from the example shown in FIGS. 4A and 4B.

The channel is the portion of the semiconductor part 252 between the source electrode 253 and the drain electrode 254. The channel length is the length between the source electrode 253 and the drain electrode 254, and the channel width is the size in the direction perpendicular to the channel length. In FIG. 4A, the channel length of the semiconductor part 252 is the channel size in the horizontal direction, and the channel width is the channel size in the vertical direction.

The thin film transistor 122 shown in FIGS. 4A and 4B is of a protected channel type. An etch stop 255 is disposed so as to cover the exposed portion of the semiconductor part 252 between the source electrode 253 and the drain electrode 254. The etch stop 255 can be made of a silicon oxide or a silicon nitride, for example. During etching of the source electrode 253 and the drain electrode 254, the etch stop 255 prevents the exposed portion of the semiconductor part 252 that is not covered by the source electrode 253 and the drain electrode 254 from being etched.

The thin film transistor 122 shown in FIGS. 4A and 4B has an offset gate structure. The offset gate structure is a structure in which the position of the gate electrode 251 is offset towards either the source electrode 253 or the drain electrode 254. In the structural example shown in FIGS. 4A and 4B, the gate electrode 251 is offset towards the source electrode side.

In the description below, the degree of offset is represented by the distance between the source electrode-side edge of the drain electrode 254 and the drain electrode-side edge of the gate electrode 251. Where the source electrode-side edge of the gate electrode 251 is fixed, if the drain electrode-side edge of the gate electrode 251 matches the source electrode-side edge of the drain electrode 254, the offset is 0.

The offset increases as the drain electrode-side edge of the gate electrode 251 moves away from the drain electrode 254. Where the offset is A for a case in which the drain electrode-side edge of the gate electrode 251 matches the drain electrode-side edge of the source electrode 253, A is positive value. The part for the offset is μm, for example. The structural example shown in FIG. 4A, the offset is A-k. k is positive value.

In the structural example shown in FIGS. 4A and 4B, the source electrode-side edge of the drain electrode 254 is parallel to the drain electrode-side edge of the gate electrode 251 and to the drain electrode-side edge of the source electrode 253. These edges are linear in the channel width direction, and extend vertically in FIG. 4A. However, these edges need not be parallel. The offset between the drain electrode 254 and the gate electrode 251 may be defined by the minimum distance therebetween.

Where the offset is 0 in FIGS. 4A and 4B, the overlapping area in a plan view between the drain electrode 254 and the gate electrode 251 is 0. The overlapping area in a plan view between the gate electrode 251 and the source electrode 253 is greater than 0. In other words, at least a portion of the gate electrode 251 overlaps the source electrode 253 in a plan view. Additionally, at least a portion of the gate electrode 251 overlaps the source electrode 253 and the semiconductor part 252.

In the example shown in FIGS. 4A and 4B, the gate electrode 251 overlaps the semiconductor part 252 but does not overlap the source electrode 253 or the drain electrode 254 in a region between an offset of 0 and an offset of A. In the range from the offset of A to the source electrode-side edge of the gate electrode 251, the gate electrode 251 overlaps the semiconductor part 252 and the source electrode 253.

In the example shown in FIGS. 4A and 4B, the source electrode-side edge of the semiconductor part 252 is farther from the drain electrode 254 than the source electrode-side edge of the gate electrode 251. The semiconductor part 252 extends further towards the photodiode side than the gate electrode 251. However, this relationship may be reversed.

As shown in FIG. 4B, the gate insulating layer 272 covers the conductive film including the gate electrode 251. The semiconductor part 252 is formed on the gate insulating layer 272. The etch stop 255 is formed on the semiconductor part 252. As shown in FIG. 4A, a portion of the bottom surface of the etch stop 255 is in contact with the semiconductor part 252 and a portion is in contact with the gate insulating layer 272.

After the gate electrode 251 and the gate insulating layer 272 are formed, the semiconductor part 252 is formed. Then, the etch stop 255 is formed, and additionally, the source electrode 253 and the drain electrode 254 are formed.

The conductive film including the source electrode 253 and the conductive film including the drain electrode 254 are formed on the semiconductor part 252. Portions of the bottom surfaces thereof are in contact with the semiconductor part 252, portions are in contact with the etch stop 255, and portions are in contact with the gate insulating layer 272. The first interlayer insulating layer 273 is formed so as to cover such constituent elements of the thin film transistor 122.

As shown in FIGS. 3A and 3B, the conductive film including the source electrode 253 is connected to the lower electrode 301 of the photodiode via the contact section formed through the first interlayer insulating layer 273. The conductive film including the drain electrode 254 is connected to the data line 106 via the contact section formed through the first interlayer insulating layer 273.

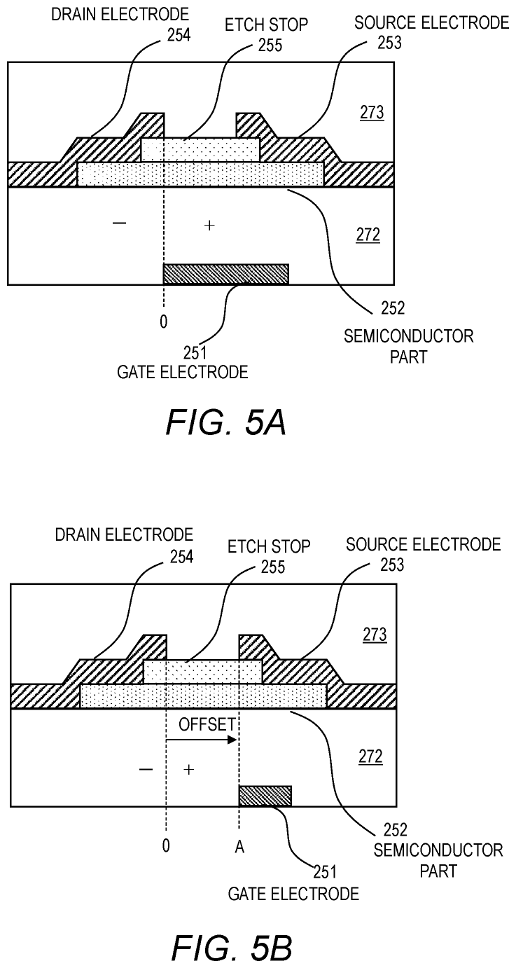

FIG. 5A is a cross-sectional view that schematically shows a cross-sectional structure of the thin film transistor 122 where the offset is 0. As described above, the offset is defined according to the source electrode-side edge (photodiode-side edge) of the drain electrode 254. In the structure where the offset is 0, the drain electrode-side edge of the gate electrode 251 matches the source electrode-side edge of the drain electrode 254.

FIG. 5B is a cross-sectional view that schematically shows a cross-sectional structure of the thin film transistor 122 where the offset is A. As described above, the offset increases moving from the drain electrode 254 towards the source electrode 253. In the structure where the offset is A, the drain electrode-side edge of the gate electrode 251 matches the drain electrode-side edge (data line-side edge) of the source electrode 253.

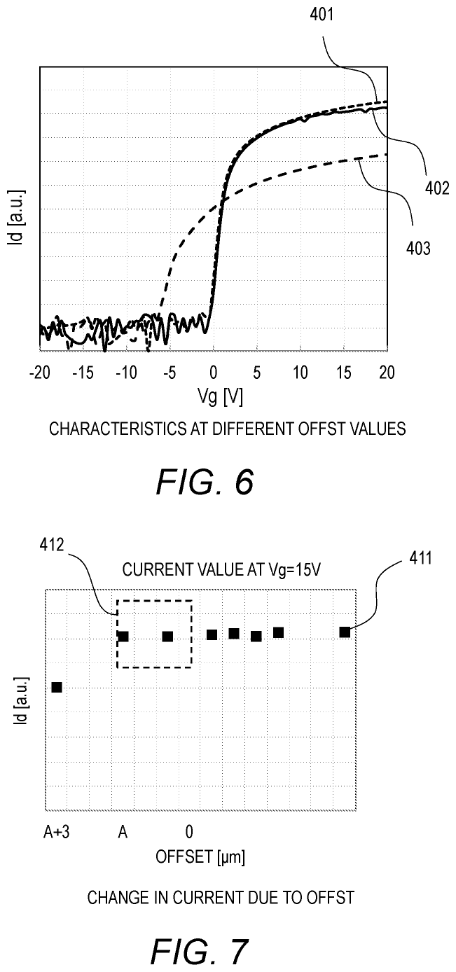

FIG. 6 shows simulation results of the structural example described with reference to FIGS. 4A to 5B of the relationship (Id-Vg characteristics) between the gate voltage Vg and the drain current Id of the thin film transistor 122 at different offset values. The horizontal axis represents the gate voltage and the vertical axis represents the drain current. The curve 401 represents Id-Vg characteristics where the offset is 0. The curve 402 represents Id-Vg characteristics where the offset is A (μm). The curve 403 represents Id-Vg characteristics where the offset is A+3 (μm).

As shown in FIG. 6, structures where the offset is 0 and the offset is A have substantially similar Id-Vg characteristics. Although not shown in the figure, at a range from a negative offset to an offset of A, the thin film transistor 122 has substantially similar Id-Vg characteristics. The offset being negative signifies that the drain electrode-side edge of the gate electrode 251 overlaps the drain electrode 254 in a plan view. As indicated by the curve 403, as the offset increases beyond A, Id is gradually reduced for positive gate voltages.

FIG. 7 shows simulation results of the relationship between the offset and the drain current Id for a gate voltage of 15V. The horizontal axis represents the offset and the vertical axis represents the drain current Id. The offset increases from right to left. The broken line 412 indicates the range from the offset of 0 to the offset of A. As shown in FIG. 7, in a range where the offset is A or less, the drain current is substantially the same.

As shown in FIG. 7, the drain current where the offset is A is substantially similar to the drain current where the offset is negative. The point 411 indicates the drain current where the overlap region between the gate electrode 251 and the source electrode 253 is substantially similar to the overlap region between the gate electrode 251 and the drain electrode 254 (a typical conventional structure), for example. As the offset increases beyond A, the drain current Id is gradually reduced.

Another simulation result (not shown) indicates that characteristics greatly differ between a gate offset structure with an offset towards the drain side and a structure with an offset towards the source side. Specifically, a great change in Id-Vg characteristics was exhibited in relation to the overlap area between the gate electrode 251 and the source electrode 253. In the simulation, the position of the drain electrode-side edge of the gate electrode 251 was fixed, and the source electrode-side edge was moved towards the drain electrode side, thereby shortening the gate electrode.

In a structure where the source electrode-side edge of the gate electrode 251 matches the source electrode-side edge of the etch stop 255, a great change started to appear in the Id-Vg characteristics. Specifically, Id decreased. Additionally, an even greater change was seen in Id-Vg characteristics in a structure where the source electrode-side edge of the gate electrode 251 is positioned between the drain electrode-side edge of the source electrode 253 and the drain electrode 254, or in other words, a structure in which the gate electrode 251 does not overlap the source electrode 253.

As described above, the size of the overlap region between the gate electrode 251 and the source electrode 253 has a great effect on the characteristics of the thin film transistor 122. On the other hand, the overlap region between the gate electrode 251 and the drain electrode 254 has substantially no effect on characteristics of the thin film transistor 122.

Thus, by setting the overlap region between the gate electrode 251 and the source electrode 253 according to desired characteristics and reducing the overlap region between the gate electrode 251 and the drain electrode 254, it is possible to reduce the capacitance (TFT capacitance Ctft) between the gate electrode 251 and the drain electrode 254 while mitigating changes in characteristics of the thin film transistor 122. The TFT capacitance Ctft is a portion of the data line capacitance Cdata, and thus, by reducing the TFT capacitance Ctft, it is possible to reduce noise occurring in the data line.

As described above, the thin film transistor has the property whereby the Id-Vg characteristics do not change even where the gate electrode and the drain electrode are offset. In operating the image sensor, the data line-side electrode is the drain and the photodetector-side electrode is the source, and the source and drain never invert. As a result, by disposing the gate electrode and the source electrode so as to overlap with a sufficient overlap region therebetween, it is possible to attain necessary characteristics for the thin film transistor and the photodetector.

Also, even if the gate electrode does not overlap the drain electrode and is separated therefrom, the drain current Id substantially does not change. Thus, through an arrangement with a small or even no overlap region between the gate electrode and the drain electrode, it is possible to reduce the TFT capacitance Ctft, which is a parameter of the data line capacitance. As a result, it is possible to attain the effect of reducing noise components having the data line capacitance as a parameter in the image sensor.

As shown in FIG. 5B, a structure where the drain electrode-side edge of the gate electrode and the drain electrode-side edge of the source electrode match (offset of A), it is possible to effectively mitigate the effect on the characteristics of the thin film transistor as well as effectively reduce the capacitance between the gate electrode and the drain electrode.

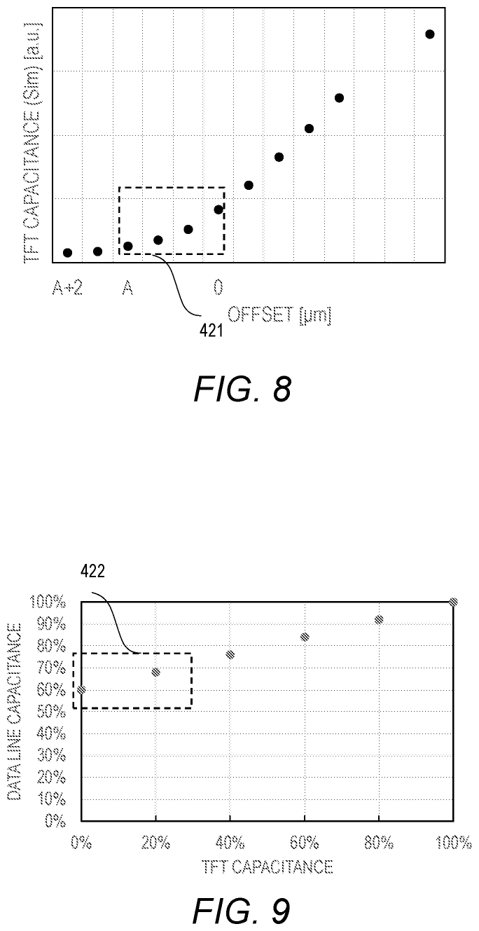

FIG. 8 shows simulation results of the relationship between the offset of the thin film transistor 122 and the TFT capacitance Ctft between the gate electrode and the drain electrode. The horizontal axis represents the offset and the vertical axis represents the TFT capacitance Ctft. The broken line rectangle 421 indicates the range from the offset of 0 to the offset of A. The TFT capacitance Ctft is reduced as the overlap region between the gate electrode and the drain electrode is reduced, and exhibits a saturation trend in the range from the offset 0 to the offset A. As the offset exceeds A, the TFT capacitance Ctft becomes substantially constant.

FIG. 9 shows simulation results for the relationship between the TFT capacitance Ctft and the data line capacitance Cdata. The horizontal axis represents the TFT capacitance and the vertical axis represents the data line capacitance Cdata. The broken line rectangle 422 indicates the range from the offset of 0 to the offset of A. At the offset of A, for example, the TFT capacitance Ctft can be reduced by approximately 25% as compared to a conventional configuration.

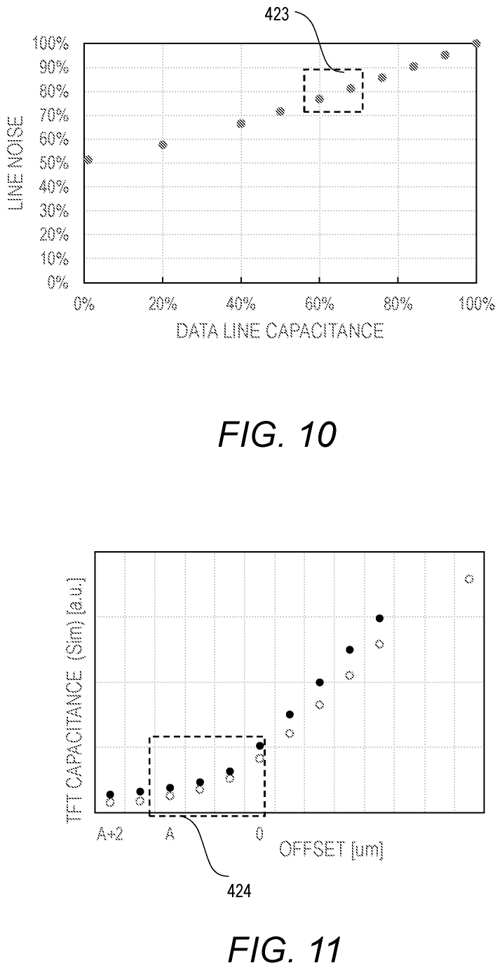

FIG. 10 shows simulation results for the relationship between the data line capacitance and noise in the data line (line noise). Where the TFT capacitance Ctft constitutes 40% of the data line capacitance Cdata, the data line capacitance Cdata is 60-70% of the value for conventional configurations as indicated by the broken line rectangle 423. Line noise having the data line capacitance Cdata as a parameter can be reduced by approximately 80% compared to conventional configurations.

The simulation results are for an etch stop-type thin film transistor as shown in FIGS. 4A and 4B. Even for a channel etch-type thin film transistor that does not include an etch stop, it is possible to reduce the TFT capacitance Ctft while reducing changes in thin film transistor characteristics in a similar offset range.

FIG. 11 shows simulation results of the relationship between the offset and the TFT capacitance Ctft for an etch stop-type thin film transistor and a channel etch-type thin film transistor. The black dots indicate simulation results for the channel etch-type thin film transistor. The white dots indicate simulation results for the etch stop-type thin film transistor. The broken line rectangle 424 indicates the range from the offset of 0 to the offset of A.

As shown in FIG. 11, no major difference is seen in the relationship between the offset and the TFT capacitance Ctft, between the two types of thin film transistors, and in particular, the relationship is substantially the same for offsets of 0 or greater. Thus, there is substantially no change in Id-Vg offset characteristics between the two types of thin film transistors. Even in the channel etch-type thin film transistor, it is possible to reduce the TFT capacitance Ctft without changes in TFT characteristics.

Below, other examples of gate electrode shapes will be described. In the examples described below, a portion of the gate electrode overlaps a portion of the source electrode in a manner similar to the other structural example. Unlike the other structural example, a portion of the gate electrode overlaps a portion of the drain electrode in a plan view. The offset defined as the distance between the source electrode-side edge of the drain electrode and the drain electrode-side edge of the gate electrode is a negative value.

The area of the overlap region between the gate electrode and the drain electrode is smaller than the area of the overlap region between the gate electrode and the source electrode. As a result, it is possible to reduce the TFT capacitance Ctft without changes in TFT characteristics. The drain electrode-side edges in the gate electrode shape examples described below overlap the drain electrodes in a plan view. The drain electrode-side edges have a recess or a protrusion. As a result, the area of the overlap region between the gate electrode and the drain electrode is reduced.

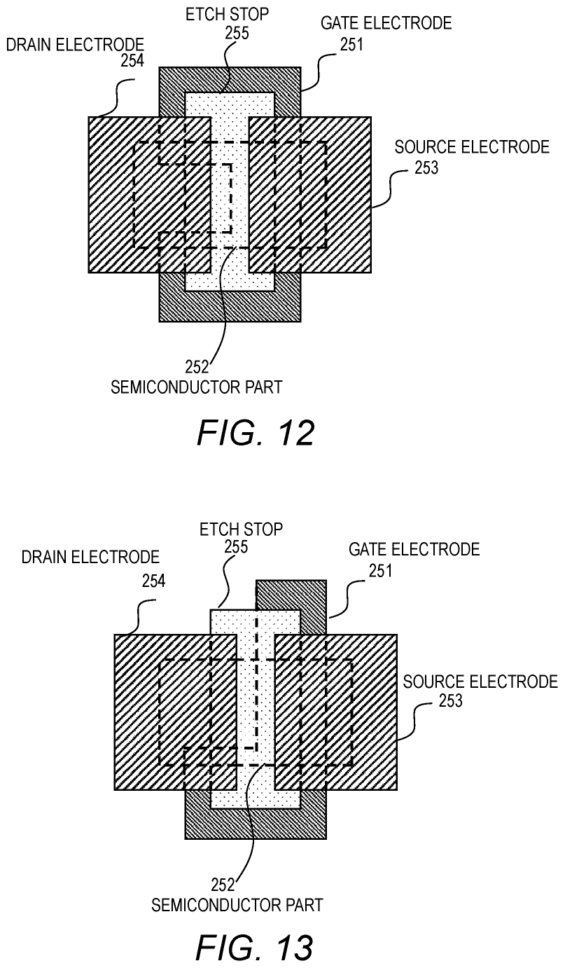

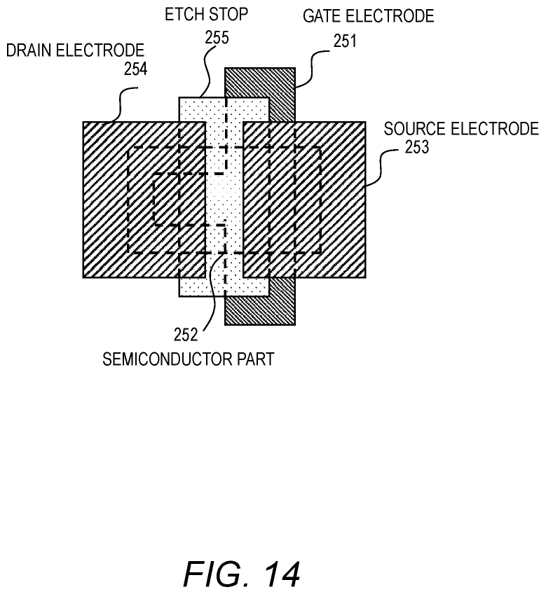

FIG. 12 shows a structural example of the thin film transistor including a gate electrode having a shape that is asymmetrical between the source electrode side and the drain electrode side. Similar to FIG. 4A, a portion of each element covered by another element is indicated with broken lines. Compared to the structural example shown in FIG. 4A, regardless of the similarity or difference in shape, the same types of constituent elements are indicated with the same reference characters. Compared to the structural example shown in FIG. 4A, constituent elements other than the gate electrode 251 have the same shape and positional relationship therebetween. These aspects similarly apply to FIGS. 13 and 14.

In the structural example of FIG. 12, the distance in the channel length direction between the drain electrode-side edge of the gate electrode 251 and the source electrode-side edge of the drain electrode 254 is the same as the distance in the channel length direction between the source electrode-side edge of the gate electrode 251 and the drain electrode-side edge of the source electrode 253. The source electrode-side edge of the gate electrode 251 is a straight line that extends in the channel width direction. On the other hand, the drain electrode-side edge of the gate electrode 251 has a recess in the center. As a result, the area of the overlap region between the gate electrode and the drain electrode is reduced.

FIG. 13 shows a structural example of the thin film transistor including a gate electrode having a shape that is asymmetrical between the source electrode side and the drain electrode side. In the structural example of FIG. 13, the distance in the channel length direction between the drain electrode-side edge of the gate electrode 251 and the source electrode-side edge of the drain electrode 254 is the same as the distance in the channel length direction between the source electrode-side edge of the gate electrode 251 and the drain electrode-side edge of the source electrode 253. The source electrode-side edge of the gate electrode 251 is a straight line that extends in the channel width direction. On the other hand, the drain electrode-side edge of the gate electrode 251 has a recess on one side. As a result, the area of the overlap region between the gate electrode and the drain electrode is reduced.

FIG. 14 shows a structural example of the thin film transistor including a gate electrode having a shape that is asymmetrical between the source electrode side and the drain electrode side. In the structural example of FIG. 14, the distance in the channel length direction between the drain electrode-side edge of the gate electrode 251 and the source electrode-side edge of the drain electrode 254 is the same as the distance in the channel length direction between the source electrode-side edge of the gate electrode 251 and the drain electrode-side edge of the source electrode 253. The source electrode-side edge of the gate electrode 251 is a straight line that extends in the channel width direction. On the other hand, the drain electrode-side edge of the gate electrode 251 has recesses on both sides and a protrusion therebetween. As a result, the area of the overlap region between the gate electrode and the drain electrode is reduced.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. An image sensor, comprising:
pixels arrayed on a substrate; and
a data line that transmits a signal read from each of the pixels,
wherein the pixel includes:
a photodetector; and
an N-type switch thin film transistor between the photodetector and the data line,
wherein the switch thin film transistor includes:
an oxide semiconductor part;
a gate electrode;
a drain electrode towards the data line; and
a source electrode towards the photodetector, and
wherein an overlap region where the gate electrode and the drain electrode overlap in a plan view is smaller than an overlap region where the gate electrode and the source electrode overlap in a plan view.

2. The image sensor according to claim 1,
wherein the gate electrode does not overlap the drain electrode in a plan view, and
wherein a portion of the gate electrode overlaps the source electrode in a plan view.

3. The image sensor according to claim 2,
wherein a drain electrode-side edge of the gate electrode is in a region between a source electrode-side edge of the drain electrode and a drain electrode-side edge of the source electrode.

4. The image sensor according to claim 2,
wherein a drain electrode-side edge of the gate electrode matches a drain electrode-side edge of the source electrode.

5. The image sensor according to claim 4,
wherein the drain electrode-side edge of the gate electrode is a straight line in a channel width direction of the oxide semiconductor part, and
wherein the drain electrode-side edge of the source electrode is a straight line in the channel width direction of the oxide semiconductor part.

6. The image sensor according to claim 1,
wherein the switch thin film transistor is connected between a cathode terminal of the photodetector and the data line.

7. The image sensor according to claim 1,
wherein the gate electrode is positioned between the oxide semiconductor part and the substrate.

8. The image sensor according to claim 7,
wherein a region of the oxide semiconductor part between the source electrode and the drain electrode is covered by an etch stop.
